(19) United States
(12) Patent Application Publication
(10) Pub. No.: US 2026/0149898 A1
(43) Pub. Date: May 28, 2026

(54) Gain Offset Compensation for Image Signal Readout

(71) Applicant: SEMICONDUCTOR COMPONENTS INDUSTRIES, LLC, Scottsdale, AZ (US)

(72) Inventor: Nicholas Paul COWLEY, Wroughton (GB)

(73) Assignee: SEMICONDUCTOR COMPONENTS INDUSTRIES, LLC, Scottsdale, AZ (US)

(21) Appl. No.: 18/962,432

(22) Filed: Nov. 27, 2024

(51) Int. Cl. H04N 25/78; H03G 3/30; H04N 17/00; H04N 25/671

(52) U.S. Cl. CPC H04N 25/78; H03G 3/30; H04N 17/002; H04N 25/671; H03G 2201/103

(57) ABSTRACT

An imaging system may include an image sensor. The image sensor may include an image sensor pixel array and image signal readout circuitry coupled to the image sensor pixel array. The readout circuitry may include adaptive gain amplifier circuitry configured to apply different gains to image signals based on their signal amplitudes. Image correction circuitry may be coupled to the amplifier circuitry and may compensate for a gain offset between image signals amplified by the different gains.

### BACKGROUND

This relates generally to imaging systems, such as systems with image sensors.

An image sensor can generate image data for electronic systems or devices. The image data can be generated by applying different gains to different image signals obtained from image sensor pixels, e.g., depending on the signal magnitude of the different image signals.

### BRIEF DESCRIPTION OF THE DRAWINGS

FIG. 1 is a diagram of an illustrative system having one or more image sensors in accordance with some embodiments.

FIG. 2 is a diagram of illustrative image sensor circuitry having an image sensor pixel array and readout circuitry for the pixel array in accordance with some embodiments.

FIG. 3 is a diagram of illustrative column readout circuitry having adaptive gain amplifier circuitry and gain offset correction circuitry in accordance with some embodiments.

FIG. 4 is a graph showing illustrative gains and corresponding gain corrections performed by readout circuitry in accordance with some embodiments.

FIG. 5 is a diagram of illustrative column readout circuitry having an adjustable amplifier, an analog-to-digital converter, and digital correction circuitry in accordance with some embodiments.

FIG. 6 is a flowchart of illustrative operations for adaptive gain compensation in accordance with some embodiments.

### DETAILED DESCRIPTION

An imaging system may include an image sensor. The image sensor may include an image sensor pixel array. Pixels of the pixel array may generate image signals that are read out using readout circuitry of the image sensor. Amplifier circuitry in the readout circuitry may use different gain settings to amplify the image signals by different gains depending on the signal magnitude of each image signal, which corresponds to the illumination level of the corresponding signal-generating pixel. While the readout circuitry can provide compensation to normalize image signals amplified by different gains provided by the different gain settings, thereby effectively aligning gain characteristics of the gain settings to have the same gain slope, some other issues may remain. As an example, there may be gain offset(s) between image signals amplified using the different gains. The gain offset(s) may be caused by switching the amplifier circuitry to apply different gain settings to image signals, may be caused by calibration using test or calibration signals that do not take into account charge injection caused by transistor switching, and/or other circuitry dynamics, that are introduced when actual image signals are output by the pixels and processed by the amplifier circuitry, and/or may be caused by other sources of mismatching effects when processing image signals using the different gain settings.

To mitigate these issues, the readout circuitry may include gain offset correction circuitry and gain offset calibration circuitry. The gain offset calibration circuitry coupled to the amplifier circuitry may use the amplifier circuitry to generate a calibrated gain offset value during a calibration time period. During an image signal readout time period, the gain offset correction circuitry may use the generated gain offset value to correct for the gain offset of applicable image signals, depending on the gain applied to each image signal. In such a manner, the gain offset of image signals, caused by any source(s) of mismatch, can be calibrated, and the calibrated value can be used for image correction.

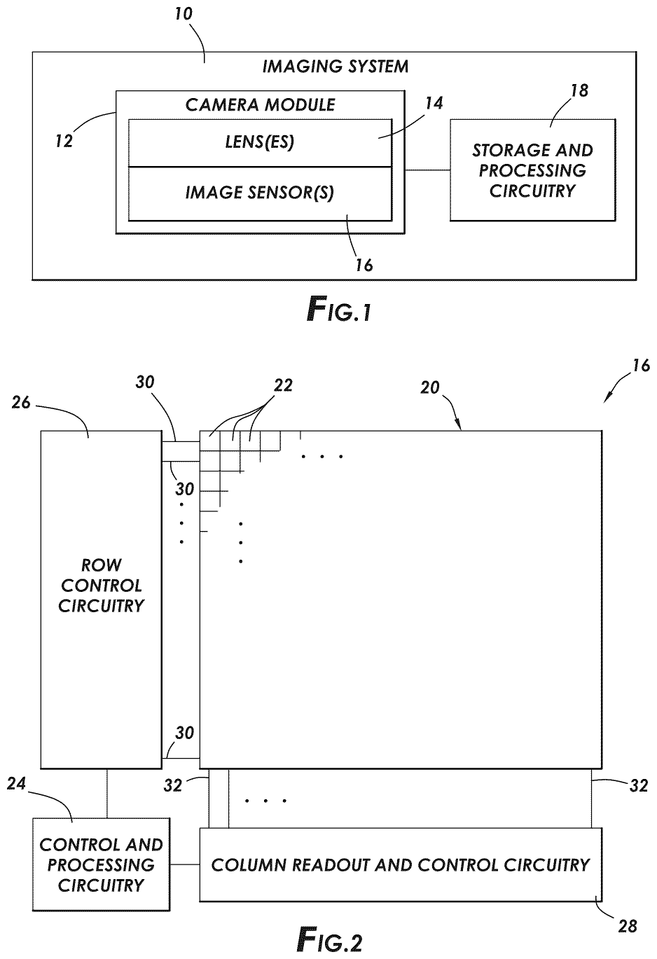

An illustrative imaging system that includes one or more image sensors, e.g., having the above-mentioned gain offset correction functionalities, is shown in FIG. 1. In particular, FIG. 1 is a functional block diagram of an illustrative imaging system such as an electronic system that uses image sensor(s) to capture images. Imaging system 10 of FIG. 1 may be a portable electronic device such as a camera, a cellular telephone, a tablet computer, a webcam, a video camera, a video surveillance system, an automotive imaging system, a video gaming system with imaging capabilities, an augmented reality and/or virtual reality system, an unmanned aerial vehicle system such as a drone, an industrial system, or any other desired imaging system or device that captures image data.

Camera module 12, sometimes referred to as an imaging module, may be used to convert incoming light into digital image data. Camera module 12 may include one or more lenses 14 and one or more image sensors 16. When capturing images, light from a scene may be focused onto each image sensor 16 by one or more lenses 14. Image sensor 16 may include circuitry for converting analog pixel image signals into corresponding digital image data that is provided to storage and processing circuitry 18.

Storage and processing circuitry 18 may include one or more integrated circuits, each serving data storage functions and/or data computation or processing functions. As examples, the one or more integrated circuits may include image processing circuits such as digital signal processors, application-specific integrated circuits, general-purpose processors, microprocessors, microcontrollers, storage devices such as voltage memory and non-volatile memory, and/or other types of integrated circuits having processors and/or memories.

Storage and processing circuitry 18 may be implemented using components that are separate from camera module 12 and/or components that form part of camera module 12. As one example, storage and processing circuitry 18 may be implemented using circuits that form part of an integrated circuit that includes an image sensor 16 or an integrated circuit within camera module 12. When storage and processing circuitry 18 is included on different integrated circuits than those of image sensors 16, the integrated circuits with storage and processing circuitry 18 may be vertically stacked or packaged with respect to the integrated circuits with image sensors 16.

Image data that has been captured by camera module 12 may be processed and stored using processing circuitry 18. As examples, an image processing engine on processing circuitry 18, an imaging mode selection engine on processing circuitry 18, and/or other types of processing engines on processing circuitry 18 may process the image data captured by camera module 12. Processing circuitry 18 may, if desired, provide processed image data to external equipment such as a computer, an external display, or other devices using wired and/or wireless communication paths.

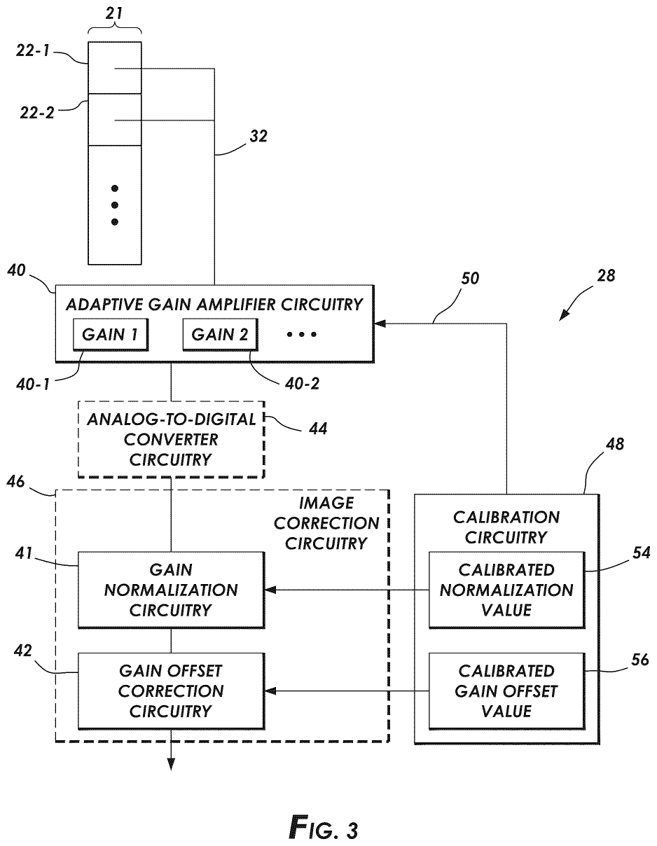

As shown in FIG. 2, an image sensor, such as an image sensor 16 included within imaging system 10 of FIG. 1, may include an image sensor pixel array such as pixel array 20 containing image sensor pixels 22, which are sometimes referred to as image pixels or pixels. These pixels 22 may be arranged in rows and columns. A row of pixels or a column of pixels may sometimes be referred to generally as a line of pixels. Image sensor 16 may include control and processing circuitry 24, sometimes referred to herein as control circuitry 24, which controls the operation of pixel array 20. Pixel array 20 may contain, for example, hundreds or thousands of rows and/or columns of image sensor pixels 22. If desired, pixel array 20 may be provided with a filter array having multiple visible color and/or non-visible filter elements each corresponding to and overlapping a respective pixel 22, thereby allowing a single image sensor to sample light of different colors and/or sets of wavelengths.

Image sensor pixels 22 may be formed in a semiconductor substrate using complementary metal-oxide-semiconductor (CMOS) technology or charge-coupled device (CCD) technology or any other suitable photosensitive device technology. Image sensor pixels 22 may be frontside illumination (FSI) image sensor pixels or backside illumination (BSI) image sensor pixels.

Control circuitry 24 may be coupled to pixel control circuitry such as row control circuitry 26 which includes row drivers that provide control signals to lines of pixels in pixel array 20 and may be coupled to pixel readout circuitry such as column readout and control circuitry 28 that read out signals from lines of pixels in pixel array 20.

Row control circuitry 26 may receive row addresses and/or signals indicative of row addresses from control circuitry 24 and supply corresponding row control signals such as reset, anti-blooming, row-select or pixel-select, charge transfer, dual conversion gain, and readout control signals to pixels 22 over conductive lines or paths 30 such as pixel row control paths. In particular, each pixel row may receive different control signals over a corresponding number of control paths such that each pixel row is coupled to multiple conductive paths 30. One or more conductive lines or paths 32 such as pixel column readout paths may be coupled to each column of pixels 22. Conductive paths 32 may be used for reading out image signals from pixels 22 and for supplying bias signals such as bias currents or bias voltages to pixels 22. As an example, when performing a pixel readout operation, a pixel row in pixel array 20 may be selected using row control circuitry 26 and image signals generated by the selected image pixels 22 in that pixel row can be read out along conductive paths 32.

Column readout circuitry 28 may receive image signals such as analog pixel values generated by pixels 22 over conductive paths 32. Column readout circuitry 28 may include memory or buffer circuitry for temporarily storing calibration signals such as reset level signals, reference level signals, and/or other non-image signals read out from array 20 and for temporarily storing image level signals read out from array 20, amplifier circuitry, analog-to-digital converter (ADC) circuitry, bias circuitry, latch circuitry for selectively enabling or disabling portions of column readout circuitry 28, and/or other circuitry that is coupled to one or more columns of pixels in array 20 for operating pixels 22 and/or for reading out image signals from pixels 22. ADC circuitry in readout circuitry 28 may convert analog pixel values received from array 20 into corresponding digital pixel values, sometimes referred to as digital image data or digital pixel data.

Column readout circuitry 28 may supply digital pixel data from pixels 22 in one or more pixel columns to control and processing circuitry 24 and/or circuitry 18 in FIG. 1 for further processing and/or storage. In particular, control and processing circuitry 24 may be formed from circuitry integrated with other circuitry of image sensor 16 such as row control circuitry 26 and/or column readout circuitry 28, and/or may be formed from discrete components such as one or more integrated circuits separate from row control circuitry 26 and/or column readout circuitry 28. The circuitry of control and processing circuitry 24 may include processing circuitry, such as digital signal processors, application-specific integrated circuits, general-purpose processors, microprocessors, and/or microcontrollers, and may include storage circuitry such as voltage memory and/or non-volatile memory.

FIG. 3 is a functional block diagram of illustrative image signal readout circuitry, e.g., forming a portion of column readout circuitry 28 in FIG. 2. In the example of FIG. 3, the portion of column readout circuitry 28 coupled to a line of pixels 22 in FIG. 2, such as pixels 22-1, 22-2, etc., is shown. In illustrative configurations described herein as an example, the line of pixels 22 may be a pixel column 21 of array 20 in FIG. 2, and the portion of readout circuitry 28 coupled to pixels 22 in pixel column 21 may be referred to as per-column readout circuitry. Accordingly, each column of pixels 22 in array 20 may be coupled to a different instance of per-column readout circuitry via a corresponding column path 32. If desired, some portions of per-column readout circuitry may be shared between multiple pixel columns.

As shown in FIG. 3, pixels 22-1, 22-2, and generally any other pixels 22 in pixel column 21 may be coupled to readout circuitry 28 via a pixel column path 32 shared by pixels 22 in column 21. Each pixel 22 of column 21, and generally, of array 20 in FIG. 2, may include one or more photosensitive elements such as photodiodes that generate charge in response to incident light (i.e., illumination), may include one or more charge storage structures such as capacitor(s) and a floating diffusion region that store portion(s) and/or all of the generated charge, may include transistors that control the flow of charge, that supply voltage(s) to different pixel elements, that serve as amplifiers such as source followers, and that are otherwise actuated to operate the pixel 22 in a desired manner, and/or may include other pixel elements. In some illustrative configurations described herein as an example, a pixel 22 may include at least a photosensitive element, a floating diffusion region, a charge transfer transistor coupled between the photosensitive element and the floating diffusion region, a source follower transistor having a gate terminal coupled to the floating diffusion region and having a source-drain terminal (i.e., a source or drain terminal) coupled to a corresponding column path 32, and a pixel select or row select transistor coupled between the source follower transistor and path 32. In general, any suitable pixel configuration may be used in connection with the embodiments described herein.

Pixels 22 in column 21 may be enabled, during the image signal readout time period, one at a time such that an image signal provided by the enabled pixel 22 can be output to readout circuitry 28, or more specifically, to the per-column readout circuitry shown in FIG. 3 via column path 32. The image signal provided by the enabled pixel 22 may be based on a portion or all of the charge generated by the photosensitive element therein during a given integration or exposure time period during which the pixel 22 is illuminated by incident light.

In particular, column path 32 in FIG. 3 may be coupled to amplifier circuitry such as adaptive gain amplifier circuitry 40. Amplifier circuitry 40 may be configured to exhibit two or more gain settings, thereby applying corresponding two or more corresponding gains to received signals, such as image signals and test, or calibration, signals. As an example, amplifier circuitry 40 may process a first input image signal using a first gain setting by amplifying the first input image signal from a given pixel 22 using a first gain 40-1. As another example, amplifier circuitry may process a second input image signal using a second gain setting by amplifying the second input image signal from the given pixel 22, or a different pixel 22, using a second gain 40-2. If desired, amplifier circuitry 40 may have one or more additional gain settings with which input image or test signals are applied with corresponding gains.

In illustrative configurations described herein as an example, amplifier gain 40-1 may be a gain greater than amplifier gain 40-2. Amplifier circuitry 40 may be configured, by using the first gain setting, to apply high gain 40-1 to any input image signals on path 32 from pixels 22 in column 21 having a signal magnitude (sometimes referred to as signal amplitude) less than a threshold signal magnitude value. Amplifier circuitry 40 may be configured, by using the second gain setting, to apply low gain 40-2 to any input image signals on path 32 from pixels 22 in column 21 having a signal magnitude greater than the threshold signal magnitude value. In such a manner, amplifier circuitry 40 may adaptively amplify an input image signal using a variable or adaptive gain based on the received signal magnitude indicative of pixel illumination level, with a higher signal magnitude indicating a higher level of illumination and a lower signal magnitude indicating a lower level of illumination. Accordingly, by amplifying low light (or low illumination) image signals (i.e., image signals below a threshold signal magnitude) using a high gain 40-1 and amplifying high light (or high illumination) image signals (i.e., image signals above the threshold signal magnitude) using a low gain 40-2, amplifier circuitry 40 may effectively extend the dynamic range of image data.

The use of two gain settings by amplifier circuitry 40 is merely illustrative. If desired, amplifier circuitry 40 may exhibit any number of adaptive gain settings based on which a corresponding gain is applied to input image signals of a range of signal magnitudes. In other words, amplifier circuitry 40 may respectively apply three levels of gains to three ranges of signal magnitudes corresponding to low, mid, and high illumination, may respectively apply four levels of gains to four ranges of signal magnitudes, etc.

Amplifier circuitry 40 may include any suitable number of fixed gain amplifiers and/or variable gain amplifiers. Different amplifiers, such as fixed gain amplifiers, of amplifier circuitry 40 exhibiting different gains may be switched into use to exhibit the different gains 40-1 and 40-2 of amplifier circuitry 40. Additionally or alternatively, one or more amplifiers, such as variable gain amplifiers, of amplifier circuitry 40 may each be configured, by adjusting switches, capacitors, and/or other tunable components therein, to exhibit the different gains 40-1 and 40-2 of amplifier circuitry 40. In particular, adaptively gain amplifier circuitry 40 may include a comparator that determines a signal magnitude of the received input signal to be amplified, may determine the gain setting to be used based on the signal magnitude, e.g., by comparing the signal magnitude to a threshold signal magnitude value, and may output an amplified version of the received input signal amplified using the determined gain setting as the output signal.

However, applying adaptive gain to image signals in the manner described above, without consideration of other effects, can sometimes worsen the signal-to-noise ratio of image data. In particular, the different amplifier gains can cause different (non-linear) mappings of input signal magnitude to output signal magnitude. While amplifier gains may effectively be normalized with respect to one another by selectively normalizing output amplified signals using gain normalization circuitry 41, there may still be a gain offset between signals applied with the different amplifier gains. This gain offset may be caused by inherent differences in the adaptive gain amplifier circuitry when applying the different gain settings, may be caused by any mismatch between the conditions and contexts of using or switching between the different gain settings, such as charge injection from the switching of transistors, and/or may be caused by other sources. The presence of this gain offset may lead to degradation of signal-to-noise ratio of image data.

To mitigate these issues, to improve signal-to-noise ratio of image data, and/or to impart other advantages, readout circuitry 28 may include gain offset correction circuitry 42, sometimes referred to as gain offset compensation circuitry 42, communicatively coupled to amplifier circuitry 40. Gain offset correction circuitry 42 may selectively process at least some of the resulting amplified signals output from amplifier circuitry 40 to compensate for the gain offset between the image signals applied with the different amplifier gains. As one example, gain offset correction circuitry 42 may include adder, subtractor, and/or other arithmetic circuits that shift an amplified signal from amplifier circuitry by the gain offset value, such that the mismatch between signals amplified by the different gains are removed. Gain offset correction circuitry 42 may be implemented in the analog domain, as analog image signal correction circuitry, or in the digital domain, as digital image data correction circuitry, depending on the desired configuration of readout circuitry 28. If desired, gain offset correction circuitry 42 may be implemented using a lookup or mapping table that maps input (digital) values containing the gain offset to corresponding output values without the gain offset.

In general, gain offset correction circuitry 42 may include any suitable circuitry used to selectively remove the gain offset present between signals amplified using a first gain setting and signals amplified using a second gain setting. If desired, gain offset correction circuitry 42 may be formed as part of other signal processing circuitry or image data correction circuitry, such as image correction circuitry 46. As described above, processing of amplified image signals output from amplifier circuitry 40 may include a normalization of at least some amplified image signals. This gain normalization or gain slope correction operation may be performed by gain normalization circuitry 41 implemented as part of image correction circuitry 46, as an example. Normalization circuitry 41 may be implemented using adder, subtractor, multiplier, divider, and/or other arithmetic circuits, may be implemented using a lookup or mapping table, and/or may be implemented in other manners to perform the normalization operation described herein.

In illustrative configurations sometimes described herein as an example, readout circuitry 28 may include analog-to-digital converter (ADC) circuitry 44 coupled between amplifier circuitry 40 and gain offset correction circuitry 42, and generally between amplifier circuitry 40 and image correction circuitry 46. ADC circuitry 44 may receive amplified analog image signals, each amplified with a corresponding gain, output from amplifier circuitry 40 and may convert the analog image signals to digital image data. ADC circuitry 44 may output the digital image data to downstream image correction circuitry 46 containing gain normalization circuitry 41 and gain offset correction circuitry 42. Accordingly, correction circuitry 46 may perform digital image data correction such as gain offset correction and gain normalization.

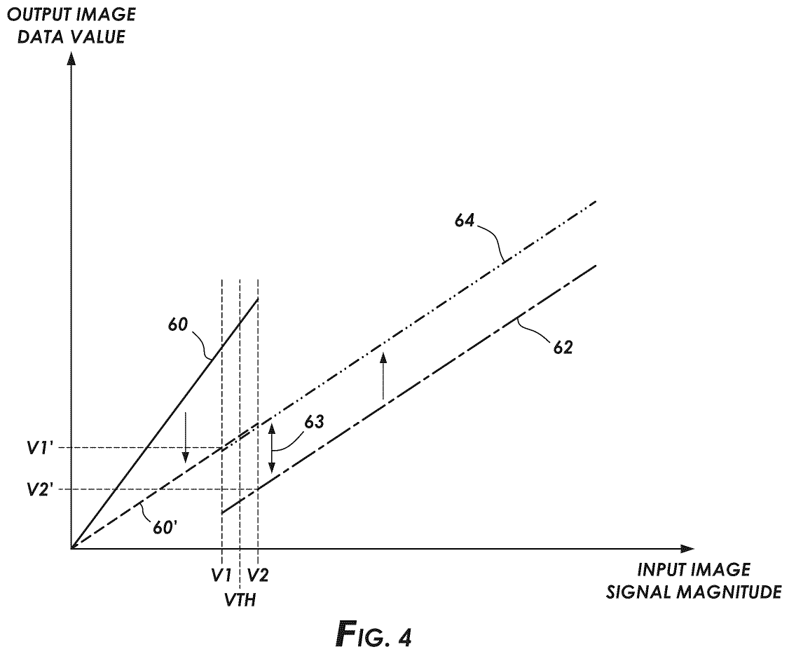

FIG. 4 is a graph of illustrative gains applied to different image signals and illustrative effects of correction operations applied to the different image signals. In the graph of FIG. 4, the input image signal or data magnitude received by amplifier circuitry 40 is plotted against the output image signal or data magnitude output by amplifier circuitry 40, or by image correction circuitry 46. In the example of FIG. 4, a greater signal magnitude (i.e., amplitude) may be indicative of higher illumination or high light conditions, while a smaller signal magnitude may be indicative of lower illumination or low light conditions.

As shown in FIG. 4, line 60 may represent input-output characteristics of a first high gain setting applied by amplifier circuitry 40 in FIG. 3, such as when gain 40-1 is applied to input signals. Line 62 may represent input-output characteristics of a second low gain setting applied by amplifier circuitry 40 in FIG. 3, such as when gain 40-2 is applied to input image signals. As described above in connection with FIG. 3, adaptive gain amplifier circuitry 40 may detect, using a comparator, whether the magnitude of the input image signal is above or below a threshold value such as threshold value VTH in FIG. 4. Responsive to the magnitude of the input image signal being less than threshold (magnitude) value VTH, amplifier circuitry 40 may apply the high gain indicated by line 60 to produce the corresponding output signal magnitude. Responsive to the magnitude of the input image signal being greater than threshold (magnitude) value VTH, amplifier circuitry 40 may apply the low gain indicated by line 62 to produce the corresponding output signal magnitude. In other words, threshold value VTH may be a transition point between the two gain settings.

In the example of FIG. 4, the output signal, when amplified using the high gain setting, may be normalized and/or otherwise modified by downstream data correction circuitry, such as gain normalization circuitry 41 in FIG. 3, such that line 60, when modified, and line 62 have the same slope. Accordingly, the normalized version of line 60 is shown as line 60′ in FIG. 4. In other words, gain normalization circuitry 41 may selectively normalize digitized version of image signals amplified using high gain 40-1 with respect to digitized version of image signals amplified using low gain 40-2, such that the normalized high-gain-amplified image data (i.e., effectively having input-output characteristics of line 60') exhibit the same gain slope as low-gain-amplified image data (i.e., having input-output characteristics of line 62).

Line 60′ indicative of a normalized high gain may still have a discontinuity with respect to line 62. This discontinuity is referred to herein as a gain offset, e.g., gain offset 63 in FIG. 4 and can cause increased signal-to-noise ratio in the image data, especially when the input signal magnitudes of the image data are close in proximity to threshold value VTH. Accordingly, it may be desirable to correct for, remove, or otherwise compensate for this gain offset.

As such, gain offset correction circuitry 42 may process amplified (and digitized image data) versions of the image signals by adding a fixed value corresponding to the magnitude of gain offset 63 to the versions of the image signals amplified using the low gain indicated by line 62. This gain-offset-corrected version of line 62 is shown as line 64 in FIG. 4.

Configured in the manner described above, even when adaptive gain is applied, the resulting image data can be corrected such that any non-linearity artifact and any discontinuity artifact resulting from adaptive gain can be removed. To properly compensate for the gain offset, the magnitude of the gain offset should be determined. Accordingly, calibration circuitry may be provided to calibrate the image correction circuitry to perform the desired image data correction operations. In illustrative configurations described herein, the image data correction operations may include correcting the gain offset from image data amplified with the second gain and normalizing the image data amplified with a first gain.

In particular, referring back to the example of FIG. 3, calibration circuitry 48 may be coupled to amplifier circuitry 40, column path 32, gain normalization circuitry 41, and gain offset correction circuitry 42. Calibration circuitry 48 may be formed as part of readout circuitry 28 and may be shared amongst and perform calibration for multiple instances per-column readout circuitry. If desired, calibration circuitry 48 may be implemented as part of control and processing circuitry 24.

To perform gain normalization calibration, calibration circuitry 48 may provide test signals via path 50 to amplifier circuitry 40 during a first calibration time period prior to an image signal readout time period. The provided test signals may each exhibit a different voltage level. The test signals may be provided by calibration circuitry 48 to an input of amplifier circuitry 40 that would receive image signals on path 32 during the image signal readout time period.

As an example, two illustrative test signals having voltages to be amplified using each gain may be provided to amplifier circuitry 40. Accordingly, two corresponding amplified versions of test signals may be received by calibration circuitry 48 for each gain setting. Using the two sets of input-output data points for each gain setting, calibration circuitry 48 may determine the gain slope of each gain setting, such as the gain slopes of lines 60 and 62 in FIG. 4 for gains 40-1 and 40-2, respectively. For example, the gain slope determination may utilize linear interpolation. Calibration circuitry 48 may further determine a calibrated normalization value 54 based on the different gain slopes. As an example, the normalization value 54 may be a scaling factor value for image data corresponding to image signals amplified using gain 40-1 to normalize the high-gain-amplified image data with respect to the low-gain-amplified image data.

During the image signal readout time period, gain normalization circuitry 41 may access normalization value 54 on corresponding storage circuitry of image sensor 16 and may apply the normalization value 54 selectively on image data corresponding to image signals amplified by gain 40-1 by scaling the image data using normalization value 54 or otherwise mapping the image data to corresponding normalized image data.

To perform gain offset correction calibration, calibration circuitry 48 may provide test signals via path 50 to amplifier circuitry 40 during a second calibration time period prior to the image signal readout time period. During the second calibration time period, which can follow the first calibration time period, test signals each exhibiting a different voltage level may be provided by calibration circuitry 48 to an input of amplifier circuitry 40 that would receive image signals on path 32 during the image signal readout time period. Amplifier circuitry 40 may amplify or otherwise process these test voltages in the same manner as image signal voltages received on path 32. As an example, test voltages below the threshold value are amplified by gain 40-1 and test voltages above a threshold voltage are amplified by gain 40-2. Calibration circuitry 48 may receive the amplified version of the test signals provided by an output of amplifier circuitry 40, e.g., after further being digitized by ADC circuitry 44 and selectively normalized by normalization circuitry 41, if the test signal is amplified using gain 40-1.

Based on the test signals provided by calibration circuitry 48 and the amplified, digitized, and selectively normalized versions of the test signals received by calibration circuitry 48, calibration circuitry 48 may determine a gain offset value for each transition point between different gains.

Calibration circuitry 48 may determine the gain offset value between first and second gains, such as gain 40-1 (after normalization) and gain 40-2, in any suitable manner. In some illustrative configurations sometimes described herein as examples, calibration circuitry 48 may provide test signals that ramp across multiple input test voltages such that a version of a first input test voltage that is closest to the input threshold voltage and that is amplified by the first gain is determined and a version of a second input test voltage that is closest to the input threshold voltage and that is amplified by the second gain is determined. The difference between the corresponding output image data based on the first and second input test voltages may be indicative of or provide an estimate of the gain offset value.

Using FIG. 4 as an example, calibration circuitry 48 may provide at least an input test voltage V1 to amplifier circuitry 40, which is amplified by amplifier circuitry 40 using gain 40-1, digitized by ADC circuitry 44, normalized by gain normalization circuitry 41, and may receive high-gain-amplified and normalized image data having image data value V1′ corresponding to input test voltage V1. Calibration circuitry 48 may provide at least an input test voltage V2 to amplifier circuitry 40, which is amplified by amplifier circuitry 40 using gain 40-2 and digitized by ADC circuitry 44, and may receive low-gain-amplified image data having image data value V2′ corresponding to input test voltage V2. Calibration circuitry 48 may determine a magnitude of gain offset 63 (i.e., the gain offset value between gain 40-1, after normalization, and gain 40-2) based on a difference between image data values V1′ and V2′. As the difference between voltages V1 and V2 of corresponding input test signals decrease, the difference between image data values V1′ and V2′ may provide a more accurate estimation of the gain offset value. If desired, other information may be used, additionally or alternatively, to determine the gain offset value.

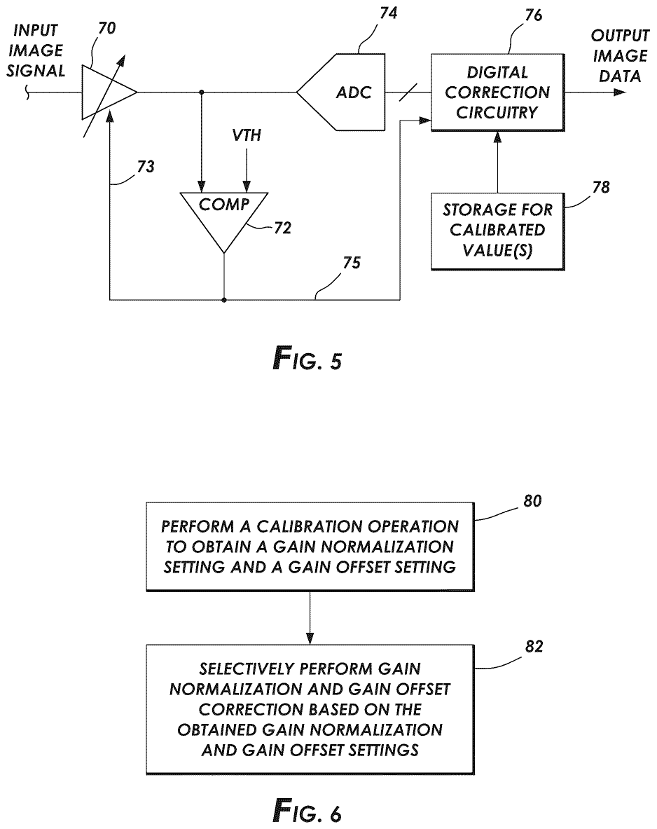

FIG. 5 is a diagram of an illustrative implementation of per-column readout circuitry of the type described in connection with FIG. 3. In particular, the per-column readout circuitry may include an adjustable (gain) amplifier 70, e.g., implementing amplifier circuitry 40 in FIG. 3. Amplifier 70 may have an input coupled to a pixel column path 32 and may be configured to receive one or more image signals, such as a first image signal from a first pixel 22-1 and second image signal from a second pixel 22-2, via the pixel column path 32. The per-column readout circuitry may include a comparator 72 having a first input coupled to an output of amplifier 70 which provides amplified version(s) of the received input image signal(s), such as image signal(s) amplified by first gain 40-1. Comparator 72 may have a second input coupled to a reference voltage source providing threshold voltage VTH. Based on the comparison of the voltage (magnitude) of the amplified image signal to threshold voltage VTH, the output of comparator 72 coupled to adjustable amplifier 70 via path 73 may provide an indication of whether the amplified image signal voltage is greater than or less than the threshold voltage. Adjustable gain amplifier 70 may (continue to) use a first gain to amplify the input image signal based on the control signal received from comparator 72 indicating that the amplified image signal voltage is less than the threshold voltage and may switch to using a second gain, less than the first gain, to amplify the input image signal based on the control signal received from comparator 72 indicating that the amplified image signal voltage is greater than the threshold voltage.

The per-column readout circuitry may include an analog-to-digital converter (ADC) 74 implementing ADC circuitry 44 in FIG. 3 and having an input coupled to the output of amplifier 70. ADC 74 may convert the amplified analog image signal received at its input to digitized image data and provide the digitized image data at its output. The per-column readout circuitry may include digital correction circuitry 76 implementing image correction circuitry 46 in FIG. 3. In particular, digital correction circuitry 76 may perform gain normalization and gain offset correction using calibrated values stored on storage circuitry 78 coupled to digital correction circuitry 76. Storage circuitry 78 may store normalization value(s) 54 and gain offset value(s) 56 in FIG. 3. In some illustrative configuration described herein as an example, circuitry 76 and 78 may be shared across multiple instances of per-column readout circuitry and a different normalization value 54 and a different gain offset value 56 may be stored and used for each instance of per-column readout circuitry.

The output of comparator 72 may also be coupled to digital correction circuitry 76 via path 75. Accordingly, comparator 72 may similarly provide the indication of whether the amplified image signal voltage is greater than or less than the threshold voltage to digital correction circuitry 76. Based on this received indication, digital correction circuitry 76 may perform the desired correction operations. As an example, correction circuitry 76 may perform normalization of image data from ADC 74 corresponding to an amplified image signal whose voltage is less than the threshold voltage, by scaling the image data by the calibrated normalization value stored on storage circuitry 78. As an example, correction circuitry 76 may perform gain offset correction of image data from ADC 74 corresponding to an amplified image signal whose voltage is greater than the threshold voltage, by adding the calibrated gain offset value stored on storage circuitry 78 to the image data. By performing these correction operations, the per-column readout circuitry may effectively exhibit an input-output gain characteristic that is linear and free of discontinuity even when multiple gain settings are switched into use.

By coupling the first input of comparator 72 to the output of amplifier 70, as shown in FIG. 5, variability between gain settings can be accounted for. However, if desired, the first input of comparator 72 may be coupled to the input of amplifier 70, instead of the output of amplifier 70.

FIG. 6 is a flowchart of illustrative operations for compensating for adaptive gain. These illustrative operations described in connection with FIG. 6 may be performed by an image sensor such as an image sensor described in connection with FIGS. 1-5.

At block 80, an image sensor may perform a calibration operation to obtain a gain normalization setting and a gain offset setting. The gain normalization setting may be defined by one or more calibrated normalization values to be selectively applied to image data or image signals amplified using one or more gains to be normalized with respect to other gain(s). The gain offset setting may be defined by one or more calibrated gain offset values to be selectively applied to image data or image signals amplified using one or more gains that exhibit discontinuities with respect to other gain(s).

As an example, the operations at block 80 may be performed by performing at least some of the operations described in connection with FIGS. 3 and 4 in connection with the first and second calibration time periods.

At block 82, an image sensor may selectively perform gain normalization and gain offset correction based on the obtained gain normalization and gain offset settings, or more specifically based on the gain normalization value(s) and gain offset value(s) defining these settings. As an example, the operations at block 80 may be performed by performing at least some of the operations described in connection with FIGS. 3-5 in connection with an image signal readout time period following the first and second calibration time periods. During the image signal readout time period, image signals from pixels 22 may be readout and received by corresponding per-column readout circuitry and processed in the manner described in connection with FIGS. 3-5.

Various embodiments have been described illustrating image sensors having readout circuitry with adaptive gain amplifier circuitry and gain offset compensation functionality.

As a first example, an image sensor may include an image sensor pixel array having a plurality of image sensor pixels, a conductive path coupled to and shared between the plurality of image sensor pixels, amplifier circuitry coupled to the conductive path and configured to receive first and second image signals along the conductive path, amplify the first image signal using a first gain, and amplify the second image signal using a second gain, and image correction circuitry coupled to the amplifier circuitry and configured to compensate for a gain offset between the first and second amplified image signals.

If desired, the first image signal may have a signal magnitude less than a threshold value and the second image signal may have a signal magnitude greater than the threshold value. If desired, the first gain may be greater than the second gain.

If desired, the image correction circuitry may be configured to compensate for the gain offset by applying a gain offset value to image data associated with the second amplified image signal. If desired, the image sensor may include calibration circuitry coupled to the amplifier circuitry and configured to determine the gain offset value and provide the determined gain offset value to the image correction circuitry. If desired, the calibration circuitry may be configured to provide test signals to the amplifier circuitry, receive versions of the test signals amplified by the amplifier circuitry, and determine the gain offset value based on the received amplified versions of the test signals. If desired, the received amplified versions of the test signals may include a first test signal amplified using the first gain and a second test signal amplified using the second gain, and the gain offset value may be determined based on a difference between the first and second amplified test signals. If desired, the calibration circuitry may be configured to determine the gain offset value during a calibration time period prior to the amplifier circuitry receiving the first and second image signals.

If desired, the image correction circuitry may be configured to perform gain normalization for image data corresponding to image signals, including the first image signal, amplified using the first gain. If desired, the image correction circuitry may be configured to compensate for the gain offset by applying a gain offset value to image data corresponding to image signals, including the second image signal, amplified using the second gain.

If desired, the image sensor may include analog-to-digital converter circuitry coupled between the amplifier circuitry and the image correction circuitry, and the image correction circuitry may include digital image data correction circuitry configured to compensate for the gain offset.

If desired, the image correction circuitry may include analog image signal correction circuitry configured to compensate for the gain offset.

As a second example, an image sensor may include an image sensor pixel array having a column of image sensor pixels, a column path coupled to the column of image sensor pixels, an adjustable gain amplifier coupled to the column path, an analog-to-digital converter coupled to the adjustable gain amplifier, and digital correction circuitry coupled to the analog-to-digital converter and including gain normalization circuitry and gain offset correction circuitry.

If desired, the image sensor may include a comparator having an output coupled to the adjustable gain amplifier. If desired, the output of the comparator may be coupled to the gain offset correction circuitry. If desired, the image sensor may include storage circuitry that stores a calibrated gain offset value and that is coupled to the gain offset correction circuitry.

As a third example, an image sensor may include an image sensor pixel array having a plurality of image sensor pixels, a conductive path coupled to and shared between the plurality of image sensor pixels, amplifier circuitry coupled to the conductive path and configured to receive an image signal on the conductive path and selectively amplify the image signal using a first gain or using a second gain based on a signal magnitude of the image signal, gain offset calibration circuitry coupled to the amplifier circuitry and configured to determine a gain offset value using test signals provided to the amplifier circuitry, and gain offset correction circuitry coupled to the amplifier circuitry and configured to compensate for a gain offset using the determined gain offset value.

If desired, the image signal may be amplified using the second gain based on the signal magnitude being greater than a threshold value, and the gain offset correction circuitry may be configured to compensate for the gain offset by adding the gain offset value to image data corresponding to the image signal amplified using the second gain.

If desired, the image signal may be amplified using the first gain based on the signal magnitude being less than a threshold value, the amplifier circuitry may be configured to receive an additional image signal on the conductive path and amplify the additional signal using the second gain based on a signal magnitude of the additional image signal being greater than the threshold value, and the gain offset correction circuitry may be configured to compensate for the gain offset by adding the gain offset value to image data corresponding to the additional image signal amplified using the second gain. If desired, the image sensor may include gain normalization circuitry coupled to the amplifier circuitry and configured to normalize image data corresponding to the image signal amplified using the first gain with respect to the image data corresponding to the additional image signal.

It will be recognized by one skilled in the art that the present exemplary embodiments may be practiced without some or all of these specific details. In other instances, well-known operations have not been described in detail in order not to unnecessarily obscure the present embodiments.

The foregoing is merely illustrative and various modifications can be made to the described embodiments. The foregoing embodiments may be implemented individually or in any combination.

What is claimed is:

1. An image sensor comprising:
an image sensor pixel array having a plurality of image sensor pixels;
a conductive path coupled to and shared between the plurality of image sensor pixels;
amplifier circuitry coupled to the conductive path and configured to receive first and second image signals along the conductive path, amplify the first image signal using a first gain, and amplify the second image signal using a second gain; and
image correction circuitry coupled to the amplifier circuitry and configured to compensate for a gain offset between the first and second amplified image signals.

2. The image sensor defined in claim 1, wherein the first image signal has a signal magnitude less than a threshold value and wherein the second image signal has a signal magnitude greater than the threshold value.

3. The image sensor defined in claim 2, wherein the first gain is greater than the second gain.

4. The image sensor defined in claim 1, wherein the image correction circuitry is configured to compensate for the gain offset by applying a gain offset value to image data associated with the second amplified image signal.

5. The image sensor defined in claim 4 further comprising:
calibration circuitry coupled to the amplifier circuitry and configured to determine the gain offset value and provide the determined gain offset value to the image correction circuitry.

6. The image sensor defined in claim 5, wherein the calibration circuitry is configured to provide test signals to the amplifier circuitry, receive versions of the test signals amplified by the amplifier circuitry, and determine the gain offset value based on the received amplified versions of the test signals.

7. The image sensor defined in claim 6, wherein the received amplified versions of the test signals comprise a first test signal amplified using the first gain and a second test signal amplified using the second gain and wherein the gain offset value is determined based on a difference between the first and second amplified test signals.

8. The image sensor defined in claim 5, wherein the calibration circuitry is configured to determine the gain offset value during a calibration time period prior to the amplifier circuitry receiving the first and second image signals.

9. The image sensor defined in claim 1, wherein the image correction circuitry is configured to perform gain normalization for image data corresponding to image signals, including the first image signal, amplified using the first gain.

10. The image sensor defined in claim 9, wherein the image correction circuitry is configured to compensate for the gain offset by applying a gain offset value to image data corresponding to image signals, including the second image signal, amplified using the second gain.

11. The image sensor defined in claim 1 further comprising:
analog-to-digital converter circuitry coupled between the amplifier circuitry and the image correction circuitry, wherein the image correction circuitry comprises digital image data correction circuitry configured to compensate for the gain offset.

12. The image sensor defined in claim 1, wherein the image correction circuitry comprises analog image signal correction circuitry configured to compensate for the gain offset.

13. An image sensor comprising:
an image sensor pixel array having a column of image sensor pixels;
a column path coupled to the column of image sensor pixels;
an adjustable gain amplifier coupled to the column path;
an analog-to-digital converter coupled to the adjustable gain amplifier; and
digital correction circuitry coupled to the analog-to-digital converter and including gain normalization circuitry and gain offset correction circuitry.

14. The image sensor defined in claim 13 further comprising:
a comparator has an output coupled to the adjustable gain amplifier.

15. The image sensor defined in claim 14, wherein the output of the comparator is coupled to the gain offset correction circuitry.

16. The image sensor defined in claim 15 further comprising:
storage circuitry that stores a calibrated gain offset value and that is coupled to the gain offset correction circuitry.

17. An image sensor comprising:
an image sensor pixel array having a plurality of image sensor pixels;
a conductive path coupled to and shared between the plurality of image sensor pixels;
amplifier circuitry coupled to the conductive path and configured to receive an image signal on the conductive path and selectively amplify the image signal using a first gain or using a second gain based on a signal magnitude of the image signal;
gain offset calibration circuitry coupled to the amplifier circuitry and configured to determine a gain offset value using test signals provided to the amplifier circuitry; and
gain offset correction circuitry coupled to the amplifier circuitry and configured to compensate for a gain offset using the determined gain offset value.

18. The image sensor defined in claim 17, wherein the image signal is amplified using the second gain based on the signal magnitude being greater than a threshold value and wherein the gain offset correction circuitry is configured to compensate for the gain offset by adding the gain offset value to image data corresponding to the image signal amplified using the second gain.

19. The image sensor defined in claim 17, wherein the image signal is amplified using the first gain based on the signal magnitude being less than a threshold value, wherein the amplifier circuitry is configured to receive an additional image signal on the conductive path and amplify the additional image signal using the second gain based on a signal magnitude of the additional image signal being greater than the threshold value, and wherein the gain offset correction circuitry is configured to compensate for the gain offset by adding the gain offset value to image data corresponding to the additional image signal amplified using the second gain.

20. The image sensor defined in claim 19 further comprising:
gain normalization circuitry coupled to the amplifier circuitry and configured to normalize image data corresponding to the image signal amplified using the first gain with respect to the image data corresponding to the additional image signal.
